(19) United States
(12) Patent Application Publication
(10) Pub. No.: US 2013/0255774 A1
(43) Pub. Date: Oct. 3, 2013

(54) PHOTOVOLTAIC CELL AND PROCESS OF MANUFACTURE

(71) Applicant: NUSOLA, INC., Burlingame, CA (US)

(72) Inventors: Jose Briceno, Tokyo-to (JP); Koji Matsumaru, Nagaoka-Shi (JP); Yusuke Nishi, Nagaoka-shi (JP)

(21) Appl. No.: 13/844,686

(22) Filed: Mar. 15, 2013

Related U.S. Application Data
(60) Provisional application No. 61/722,693, filed on Nov. 5, 2012.
(60) Provisional application No. 61/655,449, filed on Jun. 4, 2012.
(60) Provisional application No. 61/619,410, filed on Apr. 2, 2012.
(60) Provisional application No. 61/715,280, filed on Oct. 17, 2012.
(60) Provisional application No. 61/761,342, filed on Feb. 6, 2013.
(60) Provisional application No. 61/738,375, filed on Dec. 17, 2012.
(60) Provisional application No. 61/715,283, filed on Oct. 17, 2012.
(60) Provisional application No. 61/715,286, filed on Oct. 18, 2012.
(60) Provisional application No. 61/715,287, filed on Oct. 18, 2012.

(51) Int. Cl. H01L 31/18; H01L 31/0352

(52) U.S. Cl. CPC H01L 31/1804; H01L 31/035272
USPC 136/256; 438/89

(57) ABSTRACT

A material is manufactured from a single piece of semiconductor material. The semiconductor material can be an n-type semiconductor. Such a manufactured material may have a top layer with a crystalline structure, transitioning into a transition layer, further transitioning into an intermediate layer, and further transitioning to the bulk substrate layer. The orientation of the crystalline pores of the crystalline structure align in layers of the material. The transition layer or intermediate layer includes a material that is substantially equivalent to intrinsic semiconductor. Also described is a method for manufacturing a material from a single piece of semiconductor material by exposing a top surface to an energy source until the transformation of the top surface occurs, while the bulk of the material remains unaltered. The material may exhibit photovoltaic properties.

### CROSS-REFERENCE TO RELATED APPLICATIONS

This application claims the benefit of U.S. Provisional Application No. 61/761,342, filed Feb. 6, 2013 (Attorney Docket No. 44671-047 (P7)); U.S. Provisional Application No. 61/619,410, filed Apr. 2, 2012 (Attorney Docket No. 44671-033 (P2)); U.S. Provisional Application No. 61/722,693, filed Nov. 5, 2012 (Attorney Docket No. 44671-034 (P3)); U.S. Provisional Application No. 61/655,449, filed Jun. 4, 2012 (Attorney Docket No. 44671-035 (P4)); U.S. Provisional Application No. 61/738,375, filed Dec. 17, 2012 (Attorney Docket No. 44671-038 (P5)); U.S. Provisional Application No. 61/715,283, filed Oct. 17, 2012 (Attorney Docket No. 44671-041 (P12)); U.S. Provisional Application No. 61/715,286, filed Oct. 18, 2012 (Attorney Docket No. 44671-043 (P13)), and U.S. Provisional Application No. 61/715,287, filed Oct. 18, 2012 (Attorney Docket No. 44671-044 (P14)), the entireties of which are incorporated by reference as if fully set forth herein.

This application is related to copending U.S. application Ser. No. 13/______, “Single-Piece Photovoltaic Structure,” (Attorney Docket No. 44671-033-002 (P2)), filed on even date herewith and is incorporated by reference as if fully set forth herein.

### FIELD OF THE INVENTION

The present invention relates to photovoltaic devices, and in particular, a photovoltaic device structure with improved photovoltaic properties and a simplified method of manufacture.

### BACKGROUND OF THE INVENTION

Conventional methods for manufacturing photovoltaic materials typically requires some additives to a semiconductor. Such additives, including gallium arsenide (GaAs), can be highly toxic and carcinogenic, and their use in the manufacturing process of photovoltaic materials can increase the risk of negative health and environmental effects. It is highly desirable to have a manufacturing process of photovoltaic material with reduced use of additives.

The conventional methods for manufacturing photovoltaic materials also require a multi-step process, or different processes, with each step possibly taking place at a different apparatus and at different times, and requiring its own management and resources. For instance, different doping processes are applied to manufacture different semiconductor wafers, and the wafers of different types are sealed together in a particular way to form a photovoltaic material. The purpose for the doping processes and assembly of the wafers is to create p-n junctions, or p-i-n junctions, in between wafers to achieve an overall photovoltaic effect in the assembled material. Each of such manufacturing stages incurs a cost. It is highly desirable to have a manufacturing process for photovoltaic material that reduces the number of necessary processes or steps to reduce costs.

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### BRIEF SUMMARY OF PREFERRED EMBODIMENTS OF THE INVENTION

Preferred embodiments of the invention provide a novel method of manufacturing a new material with photovoltaic properties. Embodiments include processes for manufacturing using a heating process to create one or more photovoltaic structures on a semiconductor wafer, and provide the advantage of low manufacturing cost. Embodiments further include processes for reducing the resistivity of a surface opposite a high-resistivity surface on the semiconductor wafer.

### BRIEF DESCRIPTION OF THE DRAWINGS

Preferred embodiments of the present invention are illustrated by way of example, and not by way of limitation, in the figures of the accompanying drawings and in which like reference numerals refer to similar elements and in which:

FIG. 1 is diagram illustrating a view of a cross section during a heating stage of the manufacturing process according to some embodiments of the invention.

FIG. 2 is a diagram illustrating a view of a cross section of the photovoltaic material during one stage of the manufacturing process after the photovoltaic structures are formed, according to some embodiments of the invention.

FIG. 3 is a diagram illustrating a view of a cross section during one stage of the manufacturing process after one of the photovoltaic structures is removed, according to some embodiments of the invention.

FIG. 4 is a diagram illustrating a view of a cross section during one stage of the manufacturing process after formation of a silicide layer, according to some embodiments of the invention.

FIG. 5 is a diagram illustrating a view of a cross section during one stage of the manufacturing process after ion-implantation and activation process, according to some embodiments of the invention.

FIG. 6 is a diagram illustrating a view of a cross section during a heating stage of the manufacturing process of an n-on-n++-type semiconductor wafer, according to some embodiments of the invention.

FIG. 7 is a diagram illustrating a view of a cross section during one stage of the manufacturing process after formation of a photovoltaic structure above an n++-type layer, according to some embodiments of the invention.

FIG. 8 is a diagram illustrating two views of a cross section with an isolation layer before and after a heating stage of the manufacturing process according to some embodiments of the invention.

FIG. 9 is a diagram illustrating a view of a cross section during a heating stage of the manufacturing process performed with a large wafer holding structure to prevent formation of a photovoltaic layer at the bottom surface, according to some embodiments of the invention.

FIG. 10 is a diagram illustrating a view of a cross section during one stage of the manufacturing process after a heating stage, according to some embodiments of the invention.

FIG. 11 is a diagram illustrating a view of a cross section of a photovoltaic material as assembled into a photovoltaic device according to some embodiments of the invention.

FIG. 12 is a flow diagram illustrating an example of a process by which a photovoltaic material is manufactured from a semiconductor wafer and assembled into a photovoltaic device, according to some embodiments of the invention.

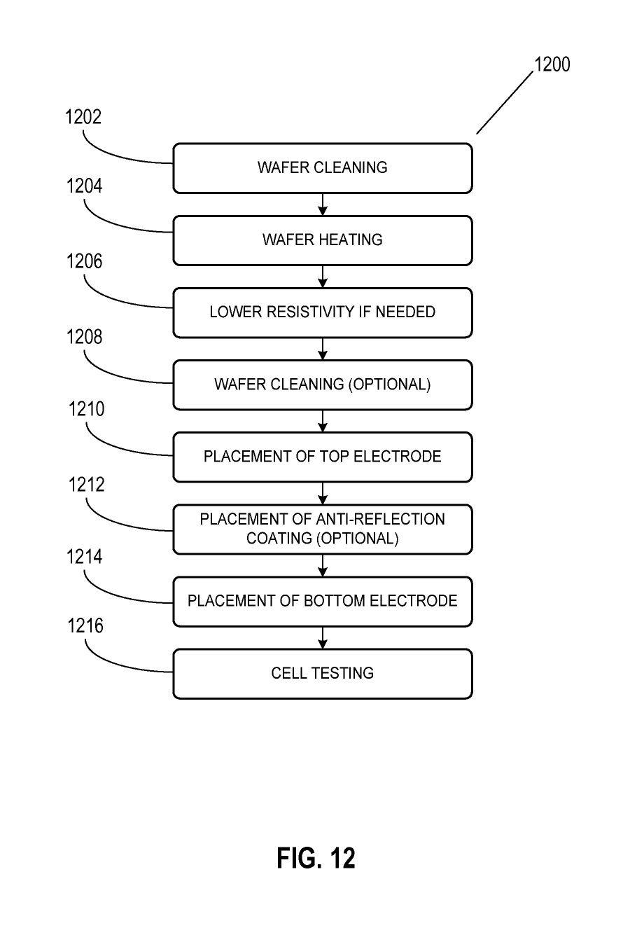

FIG. 13 is a graph illustrating the relationship between the measured open circuit voltage and the heating temperature used to create the material shown in FIG. 3 according to some embodiments of the invention.

### DETAILED DESCRIPTION OF PREFERRED EMBODIMENTS OF THE INVENTION

In the following description numerous specific details have been set forth to provide a more thorough understanding of embodiments of the present invention. It will be appreciated however, by one skilled in the art, that embodiments of the invention may be practiced without such specific details or with different implementations for such details. Additionally some well known structures have not been shown in detail to avoid unnecessarily obscuring the present invention.

### Heating Process to Create Photovoltaic Structure

According to embodiments of the invention, a semiconductor wafer having a dopant element in the wafer, is treated in a heating process to manufacture a material with photovoltaic properties. The heating process induces diffusion of the dopant element in the wafer, causing a change in the semiconductor resistivity. By controlling the mechanics of this heating process, such as heating speed, temperature, time, and cooling speed, among other parameters further described below, a photovoltaic structure forms at the surface of the semiconductor wafer.

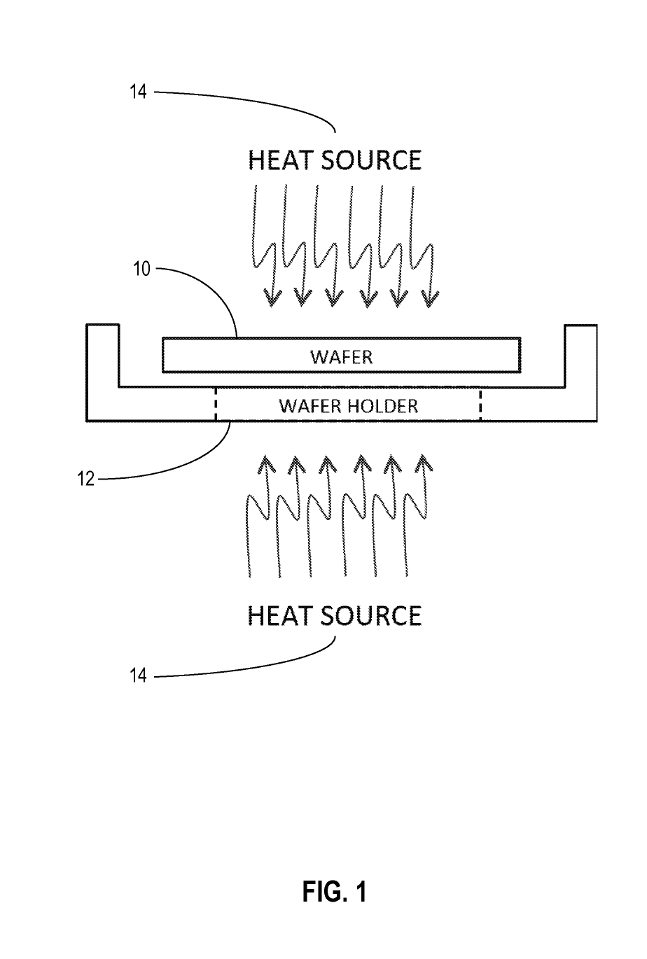

In accordance with preferred embodiments of the invention, FIG. 1 is a diagrammatic view of a cross section of semiconductor wafer 10 on wafer holding member 12 during an initial heating stage of the manufacturing process according to embodiments of the invention. In some embodiments, heat 14 is applied to the top and bottom of the wafer. When both sides of the wafer are subject to threshold conditions, including heating, photovoltaic high-resistivity layers are formed in each side of the wafer exposed to the heat source.

According to some embodiments of the invention, semiconductor wafer 10 comprises a doped single-crystal silicon wafer, such as an n-type silicon wafer. The silicon wafer has a thickness of above 10 μm. In a preferred embodiment, the silicon wafer has a thickness of 200 μm. In some embodiments, semiconductor wafer 10 comprises any one of Silicon (Si), Germanium (Ge), or any other group IV semiconductor. In some embodiments, semiconductor wafer 10 has a resistivity of 1 to 5 Ω·cm in the (100) face of crystal orientation.

The dopant element comprises any one of Phosphorus (P), Nitrogen (N), Antimony (Sb), Arsenic (As) or any other element of group V. In one example, the phosphorus content in the silicon wafer is above 0.01 ppb. In some embodiments, the phosphorus content is the minimum amount of dopant present in n-type silicon wafers as a result of standard n-type silicon wafer fabrication. For a higher concentration, phosphorus is added by methods such as ion implantation and chemical diffusion.

According to embodiments of the invention, wafer heating is performed in diverse methods, including but not limited to infrared heating, laser heating, and hot-wall furnace heating. In some embodiments, heating methods for treating semiconductor wafer 10 affect photovoltaic performance of the photovoltaic cell constructed from treated semiconductor wafer 10. In some embodiments, the cooling rate after the heating stage is a crucial factor to photovoltaic cell fabrication, whereas the heating rate is a less crucial factor to photovoltaic cell fabrication.

In a preferred embodiment, maximum photovoltaic cell performance is obtained at heating temperatures above 1500 K, at heating times above 5 minutes, at approximately 1×10⁻³ Pa. Table 1 provides a summary of parameters used in heating semiconductor wafer 10 according to embodiments of the invention.

TABLE 1
Wafer heating conditions:

| Parameter | Value Ranges | Example case |
|---|---|---|
| Heating temperature/K | 850 to 1700 | 1500 |
| Heating time/min | 1 to 600 | 5 |
| Atmosphere | Vacuum, Argon, Nitrogen, | Argon |
| | or other inert gas | |
| Treatment pressure/atm | Up to 1 | 2 × 10⁻⁴ |

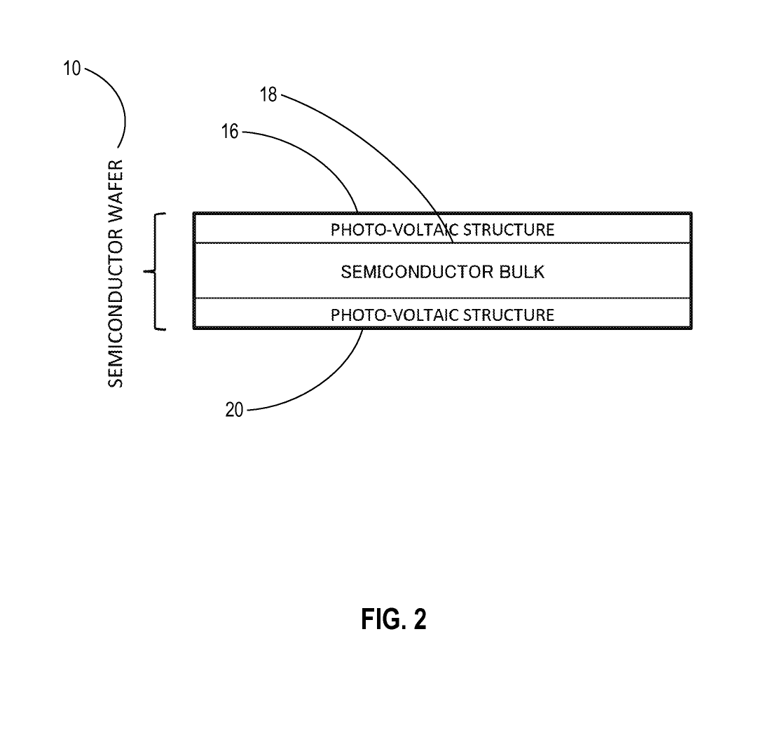

After the heating process is completed, semiconductor wafer 10 transforms into a photovoltaic semiconductor material 11 that includes the layered structures as illustrated in the diagram in FIG. 2. In the embodiment as shown, the heating process results in the formation of photovoltaic structure 16, semiconductor bulk 18, and photovoltaic structure 20 within semiconductor 10 to form photovoltaic semiconductor material 11. Photovoltaic structures 16 and 20 both include at least a high-resistivity layer therein.

### Process for Treating Bottom Surface to Lower Resistivity Thereof

According to some embodiments of the invention, after the heating process, which creates photovoltaic structures 16 and 20 when both surfaces are subjected to the conditions of Table 1, the bottom surface of photovoltaic semiconductor wafer 11 is treated to reduce its resistivity before fabricating the material into a photovoltaic cell. Treatments include but are not limited to one or more of physical removal of the bottom surface layer, formation of silicide at the bottom surface, and ion implantation into the bottom surface layer. Such lowering of resistivity at a bottom surface produces a greater output from a photovoltaic cell fabricated from the photovoltaic semiconductor wafer 11.

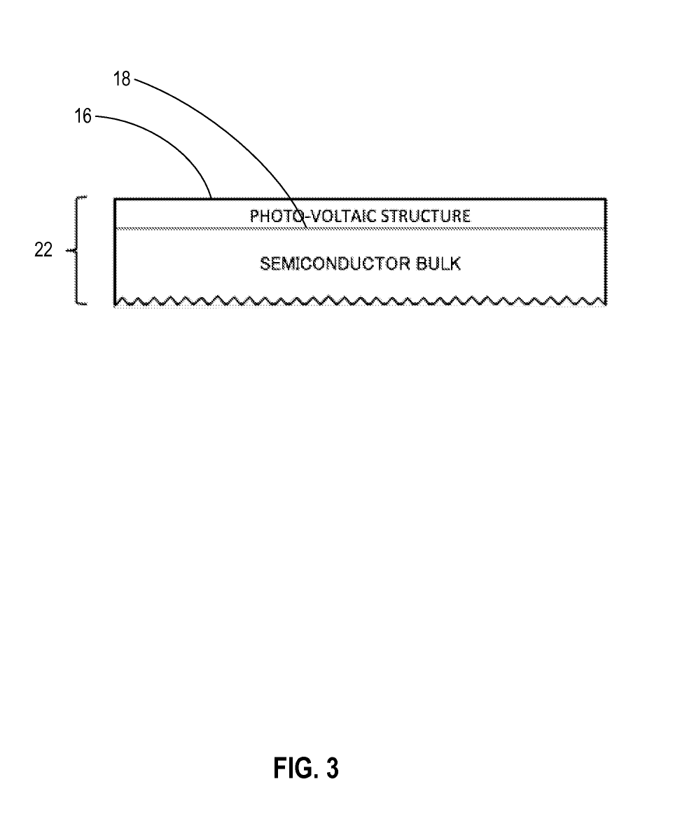

In some embodiments, a high-resistivity layer is physically removed by removal of some or all of photovoltaic structure 20. FIG. 3 is a diagram that illustrates photovoltaic semiconductor wafer 11 after heat treatment and removal according to preferred embodiments of the invention. In some embodiments, the elimination of the photovoltaic structure is achieved by physical polishing of the wafer surface, by chemical etching, or by other polishing approaches. The resulting wafer structure 22 includes photovoltaic structure 16 and semiconductor bulk 18 as shown in FIG. 3.

In some embodiments, physical polishing is achieved by polishing with an abrasive grain that can polish a silicon substrate, such as a diamond paste, alumina, or silicon carbide. As the heat processing conditions may affect the depth of the bottom high resistivity layer, the thickness of the removed layer varies. In some embodiments, the bottom surface is polished to a depth of 10 μm. In some embodiments, photovoltaic semiconductor wafer 11 is polished using chemical mechanical planarization (CMP) techniques. In some embodiments, a combination of physical polishing and CMP is used to remove material from the bottom surface of photovoltaic semiconductor wafer 11.

In some embodiments, the high-resistivity bottom surface of semiconductor 10 is removed by laser ablation using high-output beams including but not limited to YAG laser, excimer laser, argon ion laser, solid green laser, or electron beam laser, or by performing line scanning on the rear surface. In some embodiments, the ablation is provided only for the center of the substrate to prevent failure or surface leakage of the semiconductor substrate caused by fragments created during the laser ablation that have scattered onto the photovoltaic power generation layer or onto the transparent conductive film on the top surface. In some embodiments, a protective film such as polymide film is formed on the bottom surface before laser ablation, and removed by peeling and cleaning after laser ablation, to minimize scattered fragments.

In some embodiments, chemical etching is used to remove the bottom high-resistivity surface layer from photovoltaic semiconductor wafer 11. A protective film for silicon, such as a SiN film, is formed at the top surface to mask the top surface from contact with an etching chemical. The bottom side of photovoltaic semiconductor wafer 11 is dipped into the etching chemical for etching the bottom surface to a depth of approximately 10 μm. Examples of etching chemicals used include but are not limited to KOH, NaOH, mixed solution of nitric acid and hydrofluoric acid, or an etching solution in which these materials are diluted with acetic acid and water. Alternatively, dry etching may be used. After the removal of the bottom surface by etching, the protective film is removed to expose the top surface of photovoltaic semiconductor wafer 11. For example, phosphoric acid is used to remove the SiN film.

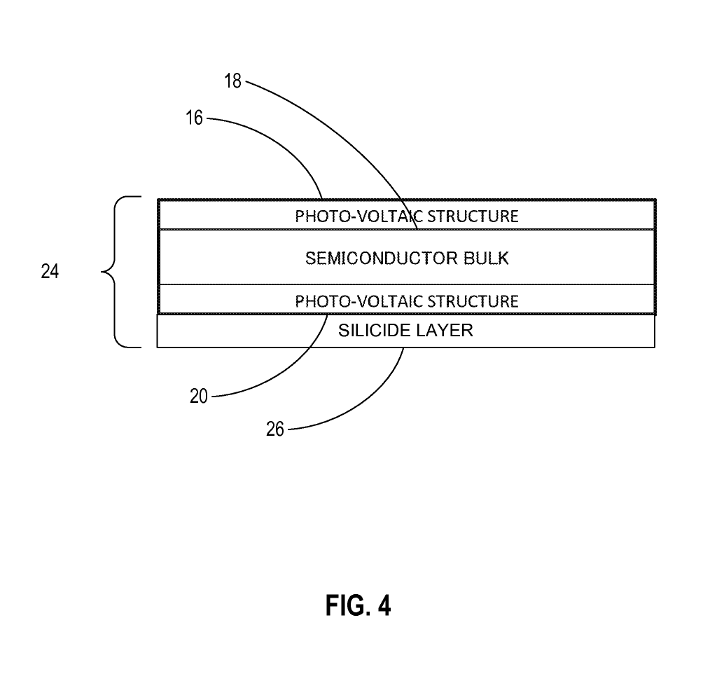

In some embodiments, treatments of the bottom surface for lowering the resistivity of the bottom surface includes formation of silicide on the rear surface of photovoltaic semiconductor wafer 11 after the heating process. FIG. 4 illustrates one example of such wafer structure 24, comprising photovoltaic structure 16, semiconductor bulk 18, photovoltaic structure 20 and silicide layer 26. To form silicide after the heating process, a preliminary metal material is formed first on the bottom surface. Such metals include but are not limited to nickel, cobalt, magnesium, lead, platinum, iron, hafnium, rhodium, manganese, titan, zirconium, titanium, chromium, molybdenum, and vanadium. Formation of the metal material onto the bottom surface may use sputtering methods including metalorganic chemical vapour deposition (MOCVD), vacuum evaporation, molecular beam epitaxy (MBE), pulsed laser deposition (PLD), or other coating method.

In some embodiments, once the metal material is formed, heat is applied to the surface to form silicide. Heating temperatures vary depending on the material used. For example, the formation of Co onto a surface of silicon requires heat processing of 620K or higher to form silicide.

The thickness of silicide necessary to lower the resistivity of the high-resistivity layer at bottom surface depends on the thickness of the high-resistivity layer. An example range of silicide formation for layer 26 is between approximately 20 nm to 10 μm.

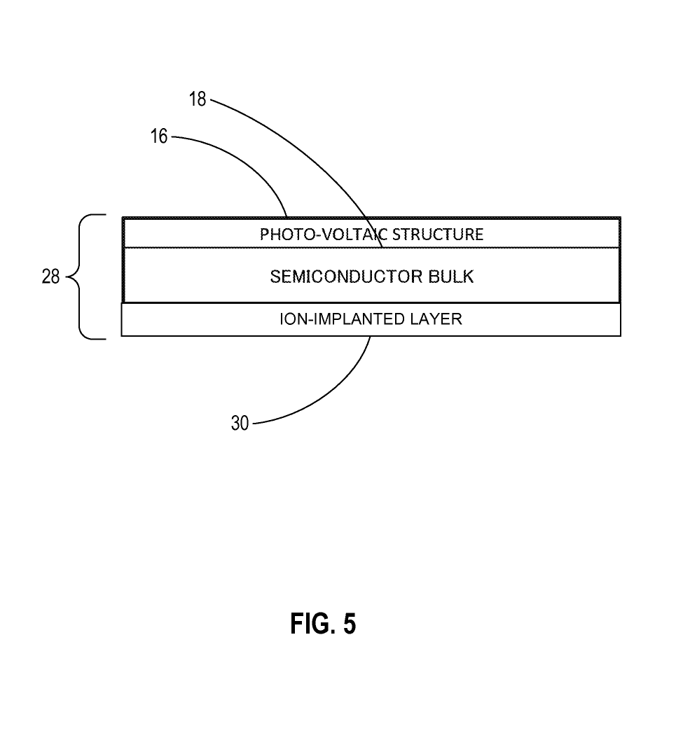

In some embodiments, treatments of the bottom surface for lowering the resistivity of the bottom surface includes ion implantation at the bottom surface to convert a portion of the material into an n++-type semiconductor. FIG. 5 illustrates the resultant ion-implanted photovoltaic material 28 transformed from photovoltaic semiconductor material 11, according to some embodiments of the invention. After the heating process to form photovoltaic semiconductor material 11, ion implantation is performed at the bottom surface to increase the concentration of the dopant in the material. For example, in some embodiments where photovoltaic semiconductor material 11 is an n-type substrate doped with phosphorus, ion implantation of phosphorus is preferred. In some embodiments, an arsenic dopant is preferred. Any range of dose amount and implantation energy may be used to achieve a desired concentration. In some embodiments, the desired concentration is 10²⁰ (cm⁻³). In some embodiments, phosphorus doping is completed by a diffusion process in a diffusion furnace instead of by ion implantation. In some embodiments, ion implantation is performed at a high energy level of 100 keV to 300 keV, followed by additional implantation at a low energy level of approximately 5 keV to 50 keV. Such an ion implantation approach first implants ions deep in the high resistivity layer, and then increases concentration to the surface thereafter. In some embodiments, following the ion implantation, dopant activation processing for activation is performed at room temperature, and activation annealing is performed, for example, in a diffusion furnace. As shown in FIG. 5, the resultant photovoltaic material 28 includes photovoltaic structure 18, semiconductor bulk 16, and at least photovoltaic material 20 transformed into ion-implanted layer 30.

### Preventative Processes to Lower Resistivity of Bottom Surface

In some embodiments, a preventative process may be performed on semiconductor 10 before the heating process reduces the resistivity of the bottom surface by preventing the formation of at least one high-resistivity layer, for example, in photovoltaic structure 20. Preventative processes performed before heating include but are not limited to using a particular type of semiconductor wafer, such as an n-on-n++ silicon substrate, that prevents formation a bottom high-resistivity layer upon heating; forming a protective film to prevent a bottom surface from forming into a high-resistivity layer upon heating; and preventing one surface from being heated to a sufficient temperature by concentrating heating to one surface or by placing semiconductor 10 on a heat reservoir to shield against the heat source.

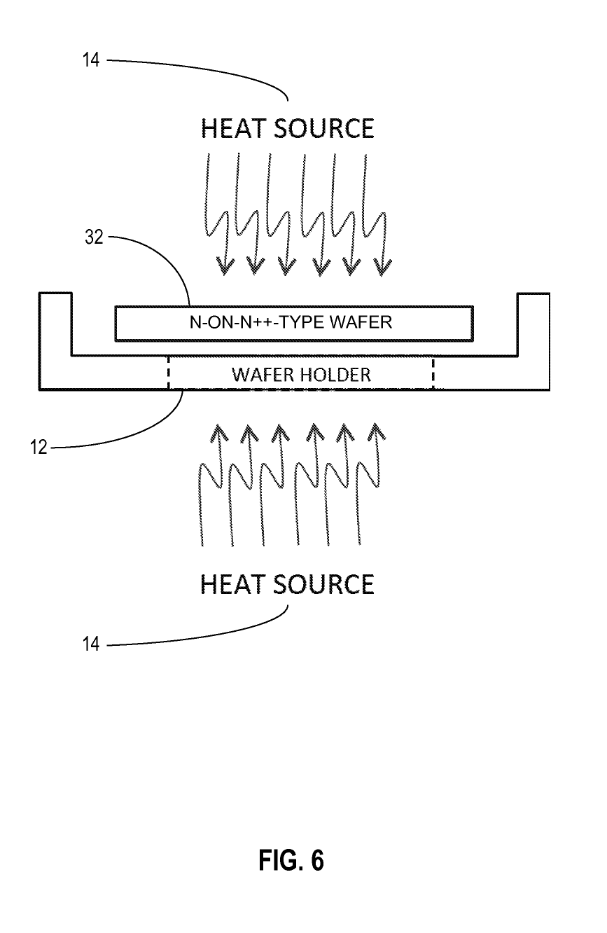

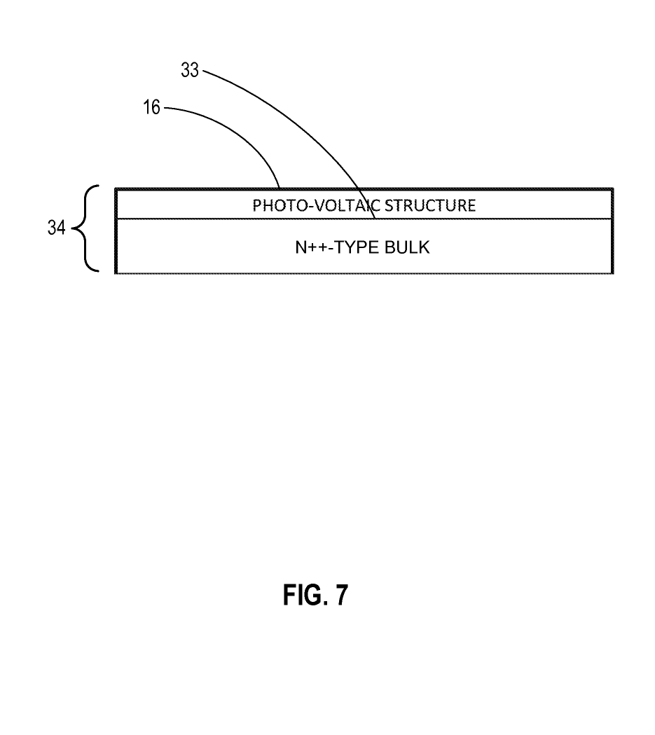

FIG. 6 illustrates the heating stage of an n-on-n++ silicon wafer 32 as the semiconductor substrate being transformed into a photovoltaic material. In some embodiments, an n-on-n++ silicon substrate may be created by first forming an n++-type silicon substrate, and then forming an n-type silicon over the n++-type silicon. In some embodiments, the n++-type silicon substrate is created by a Czochralski (CZ) process, and has a resistivity of approximately 0.001 Ω·cm. In some embodiments, the n-type silicon formed by epitaxial growth over the n++-type silicon has a resistivity of approximately 5 Ω·cm and has a thickness of approximately 5 μm. While an n++-type silicon is used in this description, an n+-type semiconductor wafer or a substrate having further lower resistivity may be used at the bottom layer without departing from the spirit of the invention. The heat process is applied to such n-on-n++-type silicon substrate, as shown in FIG. 6, under the conditions specified in Table 1, to create a photovoltaic generation layer 16 at the top surface without creating a photovoltaic layer at the bottom surface. The resultant photovoltaic material 34 comprising a photovoltaic structure 16 and a n++-type bulk 33 is shown in FIG. 7.

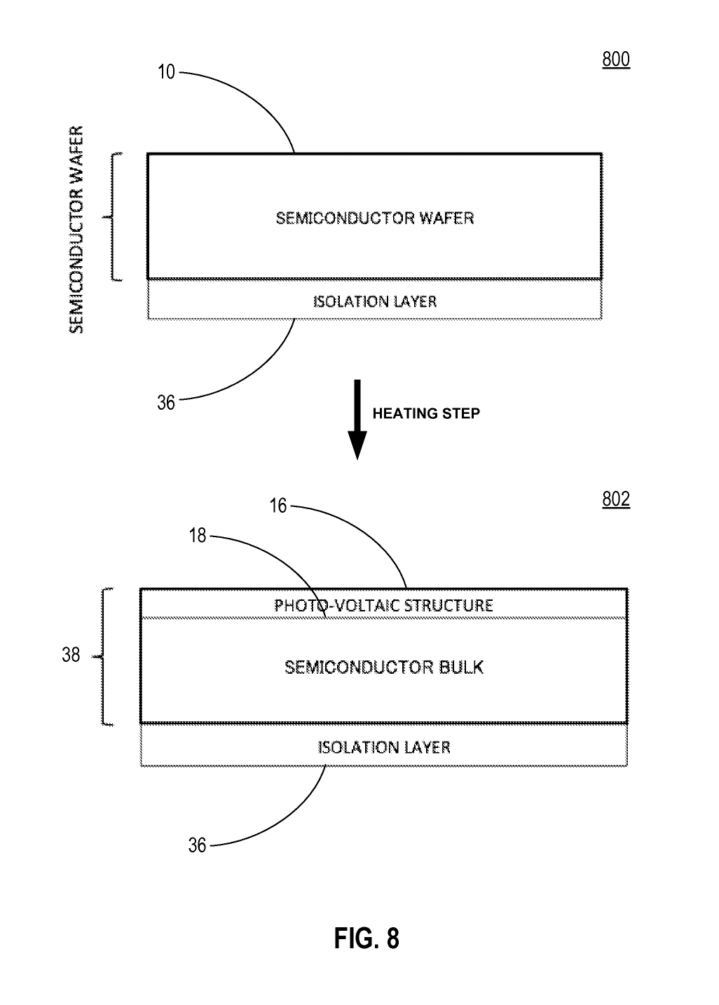

In some embodiments, as shown in the top view 800 of FIG. 8, an isolation layer or protective film 36 is formed on the bottom surface of semiconductor 10 before the heating process to prevent the high-resistivity layer from forming there during the heating process. The protective film 36 may comprise a SiN film formed at a thickness of approximately 20 nm by sputtering. After the heating step, high-resistivity photovoltaic structure 16 is formed only at the top portion of semiconductor wafer 10, as shown in the bottom view 802 of FIG. 8. The isolation layer or protective film 36 is removed before performing the next steps for completing the solar cell. While in this example, the protective film is SiN film, other materials may be used without departing from the spirit of the invention, including but not limited to: silicon-series non-organic films such as SiC, SiO₂, SiON, and SiOC, metal, metal alloy, organic material, and any material having a heat resistance equal to or higher than a temperature at which the photovoltaic layer is formed by the heating process described with reference to FIG. 1 and Table 1.

In some embodiments using SiC as isolation layer 36, the layer is not removed before forming the photovoltaic material into a photovoltaic cell because it does not negatively affect photovoltaic performance. For example, when a bottom electrode is placed on isolation layer 36 made from SiC, isolation layer 36 forms a buffer to create ohmic contact between semiconductor bulk 18 and a bottom electrode. Details of the method for using SiC to create ohmic contact between semiconductor bulk 18 and a bottom electrode is further described in copending U.S. patent application Ser. No. 13/______, filed ______, which claims priority to U.S. Provisional Application No. 61/655,449, filed Jun. 4, 2012 (Attorney Docket No. 44671-035 (P4)).

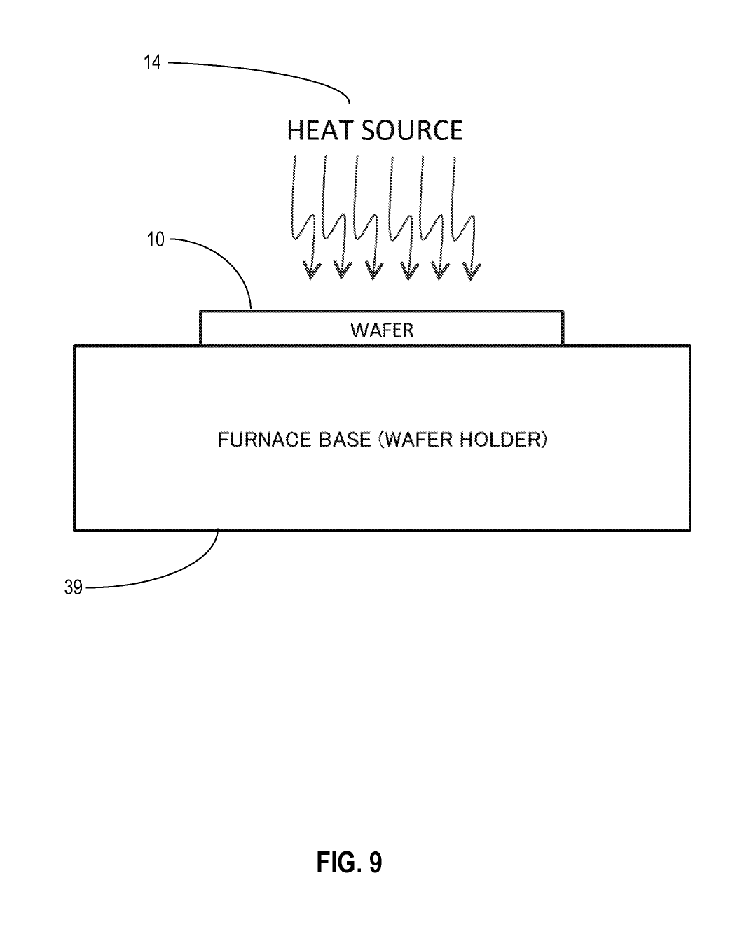

In some embodiments, as shown in FIG. 9, a preventative process includes placing semiconductor wafer 10 on a wafer holding structure or furnace base 39 comprising a cooling material, a heat dissipating material, or a heat reservoir for the heating process to prevent the bottom surface from being heated to the threshold temperature for generating a photovoltaic layer, such as the process and conditions described with reference to FIG. 1 and Table 1 above. For example, while the wafer holding structure 39 maintains the bottom surface at a temperature of approximately 1100K, the top surface reaches a desired temperature of approximately 1500K. In some embodiments, semiconductor wafer 10 is placed in direct contact with a wafer holding structure 39 configured with tungsten alloy. In some embodiments, the inside of the wafer holding structure is further cooled by water. In some embodiments, the wafer holding structure 39 is configured with a material or a shape providing a large heat capacity able to reduce the temperature of the bottom surface of semiconductor 10 without water cooling. Other materials having a relatively large mass to function as a heat reservoir and as a shield for the bottom portion and surface against the heat source may be used without departing from the spirit of the invention. For example, other high-melting-point metals may be used including molybdenum, tantalum, and niobium, and non-metal material such as quartz, may be used. In some embodiments, the assembly of a large mass wafer holder 39 in contact with semiconductor wafer 10 is introduced into a pre-heated furnace.

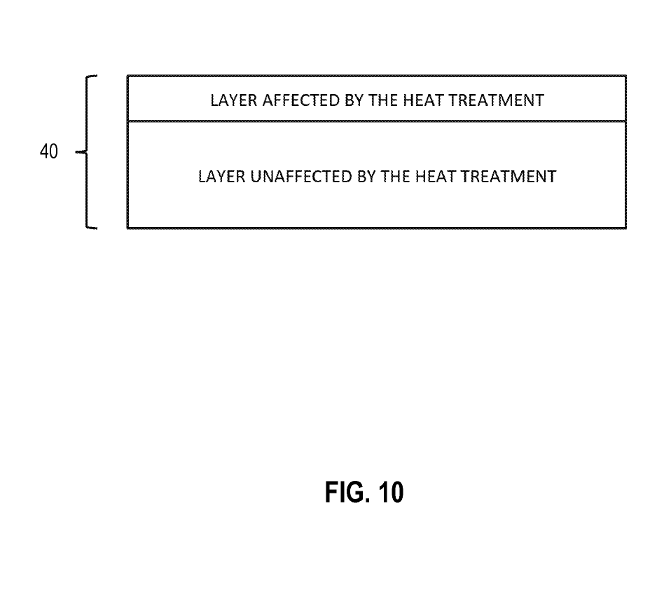

According to some embodiments, using the heating process as shown in FIG. 9, photovoltaic structure 40 comprising a top layer affected by the heat treatment and a bottom layer unaffected by the heat treatment as shown in FIG. 10 is formed.

A reduction in top surface resistivity in wafer structure 22 is desirable to optimize photovoltaic performance. In one embodiment, cell efficiency is high when the junction between the photovoltaic structure 16 and semiconductor bulk 18 is positioned relatively close to the wafer surface, or within 0.5 and 1.5 microns. When the junction is too deep into the bulk, or above 2 microns, cell efficiency starts to degrade due to the decreased penetration of light into the wafer. Treatment temperature, time, and treatment pressure are adjustable for achieving a desired position of the junction.

### Formation of Photovoltaic Cell

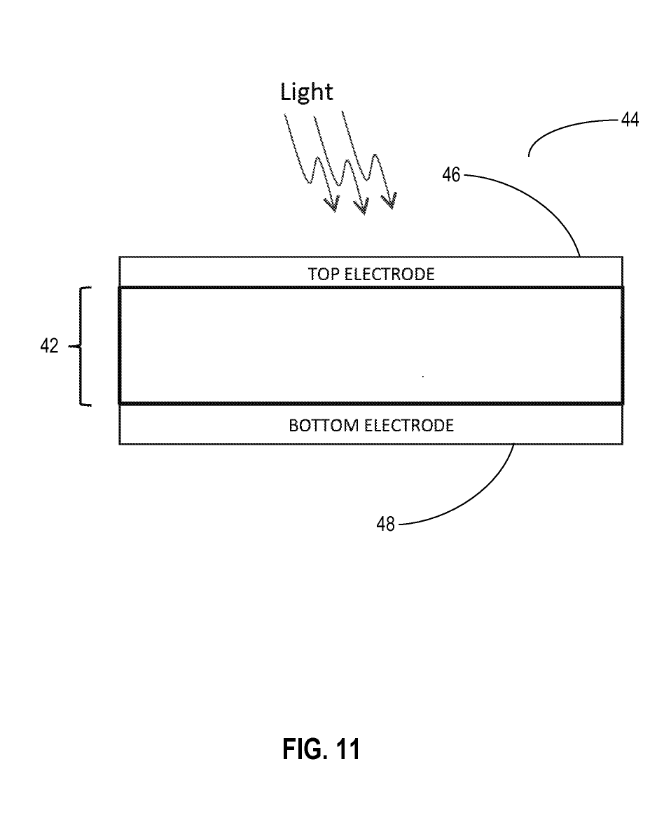

FIG. 11 illustrates an example of using a photovoltaic material 42 produced as described in any of the examples above into a photovoltaic cell. A completed cell 44 includes a top electrode 46 placed over the top surface of photovoltaic material 42. In preferred embodiments, any transparent conductive oxides (TCO), such as indium-tin-oxide (ITO), ZnO, NiO, or any other type of transparent electrodes can be used as a top electrode. Semi transparent or translucent electrodes can also be used depending on the efficiency goals and desired cost of the photovoltaic cell. An optional anti-reflecting coating may be placed on the top surface (on top of TCO layer) in order to improve light absorption and therefore cell performance.

The completed cell 44 includes bottom electrode 48. In some embodiments, an aluminum layer is preferred for bottom electrode 48. Thickness of the bottom electrode may vary between 1 and 800 microns, typically about 400 microns. A bottom aluminum electrode may be fabricated by physical vapor deposition (sputtering), screen printing, ink-jet printing or other standard printing or metal deposition techniques. Bottom electrode 48 may be placed directly over the bottom surface of photovoltaic material 42 or over a buffer in between, as previously described above with reference to related U.S. patent application Ser. No. 13/______.

### Lower-Temperature Heating Process to Reduce Crystalline Defects

In some embodiments, a photovoltaic material formed using the heating process described above with reference to FIGS. 1, 6, 8, and 9. may produce crystal defects that negatively impact the photovoltaic performance of a photovoltaic cell made from the photovoltaic material. A lower-temperature heating process, applied after the formation of the respective photovoltaic materials described above, may be used to reduce crystalline defects to increase photoelectric output. Temperature ranges for the second heat process includes temperatures higher than 650 K and lower than 1000 K, according to some embodiments of the invention. In a particular example, a heat having temperature of 870 K is applied to the photovoltaic materials for one hour in inert gas atmosphere. This lower-temperature heat process may be performed before or after the assembly of the photovoltaic material into a photovoltaic cell. Performing the lower-temperature heating after the assembly of the photovoltaic cell provides the advantage of removing any binder from the aluminum bottom electrode by the second heating.

### Process for Manufacturing Photovoltaic Material and Cell

The steps in a process 1200 according to some embodiments of the invention for creating a photovoltaic material and cell is described with reference to a flowchart in FIG. 4. At step 1202, wafer cleaning is performed. In some embodiments, silicon wafers are cleaned by dipping the wafers into a solution of hydrofluoric acid, followed by water cleaning and air drying. This process mainly targets the removal of the natural oxide film formed on the wafer surface.

At step 1204, wafer heating is performed. Heat sources are applied to the top and the bottom of the wafer under the conditions described in Table 1 above. At step 1206, process for lowering the resistivity of the bottom layer is performed. Processes for lowering resistivity of the bottom layer include but are not limited to physical removal of the bottom surface layer, formation of silicide at the bottom surface, and ion implantation into the bottom surface layer to convert a portion of the material into an n++-type semiconductor. In some embodiments, step 1206 is performed prior to step 1204. Processes for lowering resistivity of the bottom layer prior to a heating step include but are not limited to using a particular type of semiconductor wafer, such as an n-on-n++ silicon substrate, that prevents formation a bottom high-resistivity layer upon heating; forming a protective film to prevent a bottom surface from forming into a high-resistivity layer upon heating; and preventing one surface from being heated to a sufficient temperature by concentrating heating to one surface or by placing semiconductor on a heat reservoir to shield against the heat source.

At step 1208, wafer cleaning is optionally performed if necessary. At step 1210, a top electrode is placed over the photovoltaic structure 16 of the wafer. In preferred embodiments, any transparent conductive oxides (TCO), such as indium-tin-oxide (ITO), ZnO, NiO, or any other type of transparent electrodes can be used as a top electrode. Semi transparent or translucent electrodes can also be used depending on the efficiency goals and desired cost of the photovoltaic cell.

At step 1212, an optional anti-reflecting coating may be placed on the top surface (on top of TCO layer) in order to improve light absorption and therefore cell performance.

At step 1214, placement of bottom electrode occurs. In some embodiments, an aluminum layer is preferred for the bottom electrode. Thickness of the bottom electrode may vary between 1 and 800 microns, typically about 400 microns. A bottom aluminum electrode may be fabricated by physical vapor deposition (sputtering), screen printing, ink-jet printing or other standard printing or metal deposition techniques. At step 1216, cell testing is optionally performed to verify the photovoltaic device and to test performance.

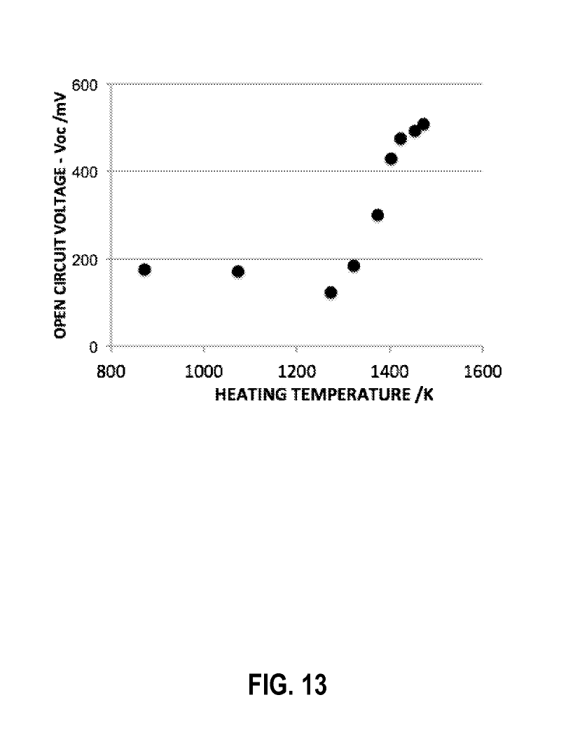

In one embodiment, measurement of an open circuit voltage (V_{OC}) is used to test the performance of the cell. FIG. 13 is a graph that shows the measured V_{OC} for a particular heating temperature used to create a photovoltaic wafer structure according to the techniques discussed above. Improved photovoltaic cell performance is shown for heating temperatures above 1350K. In particular, the V_{OC} nearly doubles between 1350K and the highest temperature shown on the graph.

Other features, aspects and objects of the invention can be obtained from a review of the figures and the claims. It is to be understood that other embodiments of the invention can be developed and fall within the spirit and scope of the invention and claims.

The foregoing description of preferred embodiments of the present invention has been provided for the purposes of illustration and description. It is not intended to be exhaustive or to limit the invention to the precise forms disclosed. Various additions, deletions and modifications are contemplated as being within its scope. The scope of the invention is, therefore, indicated by the appended claims rather than the foregoing description. Further, all changes which may fall within the meaning and range of equivalency of the claims and elements and features thereof are to be embraced within their scope.

What is claimed is:

1. A photovoltaic material comprising:
a photovoltaic semiconductor material with one or more photovoltaic structures at one or more surfaces, whereby the semiconductor material with the one or more photovoltaic structures is created by performing the steps of:
exposing a single-piece semiconductor material to an energy source, whereby the whereby the energy source causes heating of a portion of the single-piece semiconductor material; and
ceasing exposure of the single-piece semiconductor material to an energy source, whereby the exposing step and the ceasing step cause the single-piece semiconductor material to transform into the photovoltaic semiconductor material with one or more photovoltaic structures at one or more surfaces.

2. The photovoltaic material of claim 1, created by further performing the steps of:
performing processes for creating a photovoltaic material with lowered resistivity at a bottom surface of the photovoltaic semiconductor material whereby the lowered resistivity causes a photovoltaic cell using the photovoltaic material to produce greater output than without a lowered resistivity.

3. The photovoltaic material of claim 1, created by further performing the steps of:
treating the bottom surface of the photovoltaic semiconductor material by performing any one of:
physical removal of the bottom surface layer;
formation of suicide at the bottom surface layer;
ion implantation into the bottom surface layer.

4. The photovoltaic material of claim 1, created by further performing the steps of:
performing preventative processes to the single-piece semiconductor material prior to the exposing and ceasing steps by performing any one of:
forming a protective film on a bottom surface to prevent the bottom surface of the single-piece semiconductor material from forming into a high-resistivity layer upon heating;
concentrating the exposing of the energy source to one surface of single-piece semiconductor material, whereby the concentrating prevents the other surface from reaching a target temperature for transforming the other surface into a photovoltaic structure;
placing the single-piece semiconductor material onto a heat reservoir for the exposing step, whereby the placing prevents the other surface from reaching a target temperature for transforming the other surface into a photovoltaic structure;
performing the exposing and the ceasing steps on an n++ silicon substrate, whereby the exposing and ceasing steps cause a n-type silicon to form over the n++ silicon substrate to form an n-on-n++ photovoltaic material.

5. The photovoltaic material of claim 4, wherein the protective film includes a SiC layer, and forming a metal bottom electrode thereon after the exposing and the ceasing to form an ohmic contact in a metal-to-semiconductor interface.

6. The photovoltaic material of claim 1, created by further performing the steps of:
performing a second heating the photovoltaic material at a temperature that is lower than heating in the exposing step, whereby the second heating causes removal of crystalline defects in the one or more photovoltaic structures.

7. The photovoltaic material of claim 1, wherein the portion of the single-piece semiconductor material is heated to a temperature of between 850 K and 1700 K.

8. The photovoltaic material of claim 1, wherein the steps of exposing and ceasing occurs in a vacuum.

9. The photovoltaic material of claim 1, wherein the heating of the portion occurs for a duration of 1 to 600 minutes.

10. The photovoltaic material of claim 1, wherein the single-piece semiconductor material is an n-type silicon, the n-type silicon having an impurity of phosphorus.

11. The photovoltaic material of claim 1, wherein the one or more photovoltaic structures includes a high-resistivity layer therein.

12. The photovoltaic material of claim 1, wherein the single-piece semiconductor material comprises any one of germanium or other group IV semiconductor.

13. The photovoltaic material of claim 1, wherein the single-piece semiconductor material comprises any one of germanium or other group IV semiconductor, and has an impurity of any one of phosphorus, nitrogen, antimony, arsenic, or other group V element.

14. The photovoltaic material of claim 1, wherein the single-piece semiconductor material has a resistivity of 1 to 5 Ω·cm in the (100) face of crystal orientation.

15. The photovoltaic material of claim 1, wherein the single-piece semiconductor material has a thickness of at least 10 μm.

16. The single-piece photovoltaic material of claim 1, wherein the single-piece photovoltaic material produces photovoltaic effects when exposed to light.

17. A photovoltaic device using the single-piece photovoltaic material according to claim 1, the photovoltaic device comprising:
the single-piece photovoltaic material;
a bottom electrode provided under the single-piece photovoltaic material; and
a top electrode provided over the single-piece photovoltaic material.

18. A method for manufacturing a photovoltaic material, comprising performing the steps of:
exposing a single-piece semiconductor material to an energy source, whereby the whereby the energy source causes heating of a portion of the single-piece semiconductor material; and
ceasing exposure of the single-piece semiconductor material to an energy source, whereby the exposing step and the ceasing step cause the single-piece semiconductor material to transform into the photovoltaic semiconductor material with one or more photovoltaic structures at one or more surfaces.

19. A photovoltaic material comprising:
a photovoltaic semiconductor material with one or more photovoltaic structures at one or more surfaces, whereby the semiconductor material with the one or more photovoltaic structures is created by performing the steps of:
exposing an n-type silicon wafer to an energy source, whereby the whereby the energy source causes heating of a portion of the n-type silicon wafer; and
ceasing exposure of the n-type silicon wafer to an energy source, whereby the exposing step and the ceasing step cause the single-piece semiconductor material to transform into the photovoltaic semiconductor material with one or more photovoltaic structures at one or more surfaces, the one or more photovoltaic structures having a high resistivity layer therein;
forming a protective film of SiC layer on a bottom surface of to prevent the bottom surface of the single-piece semiconductor material from forming into a high-resistivity layer upon heating; and
placing a metal bottom electrode over the SiC layer, whereby the metal-to-semiconductor interface between the metal bottom electrode and the n-type silicon wafer forms an ohmic contact.
